(19) United States
(12) Patent Application Publication
(10) Pub. No.: US 2002/0072190 A1
(43) Pub. Date: Jun. 13, 2002

(54) Method of fabricating a cylinder capacitor having a reverse electrode structure

(76) Inventors: Tzung-Han Lee, Taipei (TW); Alex Hou, Kaohsiung (TW); King-Lung Wu, Tainan Hsien (TW)

Correspondence Address: CHARLES C.H. WU & ASSOCIATES, Suite 710, 7700 IRVINE CENTER DRIVE, Irvine, CA, 92618-3043, US

(21) Appl. No.: 09/745,278

(22) Filed: Dec. 20, 2000

(30) Foreign Application Priority Data
Dec. 12, 2000 (TW) 89126420

(51) Int. Cl. H01L 21/20

(52) U.S. Cl. 438/396

(57) ABSTRACT

A method of manufacturing a reverse electrode cylinder capacitor structure is described. A substrate having a dielectric layer and a node contact window formed thereon is provided. The dielectric layer is etched, thereby forming an opening that exposes the node contact window, and is connected to the openings formed on the two adjacent node contact windows, forming the neck-shaped structure. Next, a conductive spacer is formed on the sidewall of the opening, the conductive spacer is connected to the neck-shaped structure and forms the upper electrode of the capacitor. A dielectric layer is formed on the upper electrode, and a conductive layer is formed on the dielectric layer. A conductive layer is deposited to fill up the node contact window opening, thereby the formed conductive layer becomes the lower electrode. After performing a planarization process, the reverse electrode cylinder capacitor structure is complete.

### CROSS-REFERENCE TO RELATED APPLICATION

This application claims the priority benefit of Taiwan application Ser. no. 89126420, filed Dec. 12, 2000.

### BACKGROUND OF THE INVENTION

1. Field of the Invention

The present invention relates to a method of manufacturing a memory device. More particularly, the present invention relates to a method of manufacturing cylinder capacitor having a reverse electrode.

2. Description of the Related Art

A capacitor is an important device in the DRAM to prevent the stored materials in the DRAM from errors and to increase the DRAM operation efficiency. Usually a stereoscopic capacitor with a great surface area is manufactured, such as the commonly seen cylinder capacitor, for example.

The method of manufacturing a cylinder capacitor in the related art is illustrated in FIGS. 1A to IC. Referring to FIG. 1A, a dielectric layer 102 is formed a substrate 100. A node contact window 104 is formed in the substrate 100. The node contact window 104 and the substrate 100 are electrically connected. A dielectric layer 106 is formed on the substrate 100. An opening 108 is formed within the dielectric layer 106, wherein the opening 108 exposes the node contact window 104. A polysilicon layer 110 is formed within the opening 108 and upon the dielectric layer 102.

Subsequently, referring to FIG. 1B, the polysilicon layer 110 covering the outside of the opening 108 and above the dielectric layer 106 is removed. Thus, the remaining polysilicon layer 110 in the inner wall and the bottom portion of the opening 108 forms the lower electrode 112 of the cylinder capacitor.

Finally, referring to FIG. 1C, a thin dielectric layer 114 is deposited onto the lower dielectric layer 112. Next, another polysilicon layer 116 is formed upon the dielectric layer 114, thereby forming the upper electrode of the cylinder capacitor, and completes the structure of the cylinder capacitor.

In the manufacturing method of the cylinder capacitor in the related art, during removal of the polysilicon layer 110 outside of the opening 108 and above the dielectric layer 106, chemical mechanical polishing (CMP) is used. However, the residual solvent of the polishing plasma used in the CMP process enters the region of the opening 108. As a result, not only is the successive formation process of the dielectric layer 114 affected, but also the lower electrode 112 and the dielectric layer 114 are contaminated.

### SUMMARY OF THE INVENTION

The invention provides a method of manufacturing a cylinder capacitor. An upper electrode is formed. Then, a dielectric layer is formed on the upper electrode. Thereafter, a lower electrode is formed. Thus, a reverse electrode structure is formed.

The invention provides another method of manufacturing a cylinder capacitor, whereby the CMP slurry is prevented from entering the inner cylinder capacitor and contaminating the lower electrode and the dielectric layer.

As embodied and broadly described herein, the invention provides a method of manufacturing a cylinder capacitor having a reverse electrode structure. The process includes forming a dielectric layer upon the substrate having the node contact window formed therein. The dielectric layer is etched for forming an opening that exposes the node contact window, while the opening is connected to an adjacent opening formed upon the two adjacent node contact windows, and forms a neck-shaped structure. Subsequently, a conductive spacer is formed on the sidewall of the opening, and a portion of the conductive layer and the dielectric layer are removed, thereby exposing the node contact window. Next, another conductive layer is deposited, filling up the node contact window; hence, the formed conductive layer becomes the lower electrode. Through a planarization process, the reverse electrode cylinder capacitor structure is completed. As per the description of the embodiment, the important features of the present invention are formation of the upper electrode of the cylinder capacitor, and subsequent formation of the dielectric layer and the lower electrode. Also, the present invention of the cylinder capacitor has a reverse electrode structure, wherein the capacitor is structured as having the lower electrode, dielectric layer and the upper electrode from top to bottom. The capacitor of the present invention is structurally opposite to the conventional capacitor. During the formation of the capacitor, the polishing slurry is prevented from entering the cylinder structure. Thus, the CMP process would not cause a contamination to the conductive layer and the dielectric layer .

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention, and, together with the description, serve to explain the principles of the invention. In the drawings,

FIGS. 1A to 1C are manufacturing flow diagrams illustrating a cylinder capacitor in the related art;

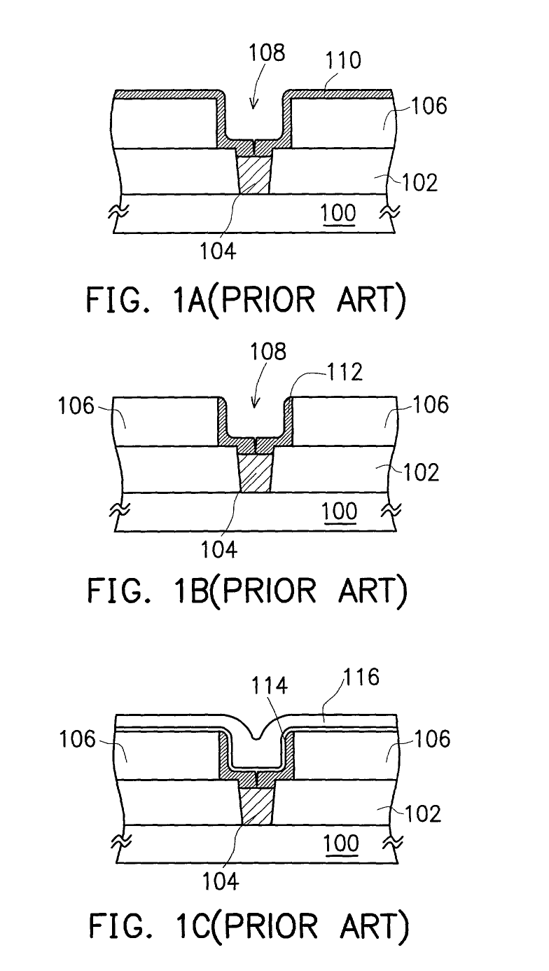

FIGS. 2A to 2E are manufacturing flow diagrams illustrating a cylinder capacitor according to one preferred embodiment of the present invention;

FIG. 3A is a side-view diagram illustrating an opening structure according to one preferred embodiment of the present invention;

FIG. 3B is a top-view diagram illustrating an opening structure according to one preferred embodiment of the present invention; and

FIG. 3C is a structural diagram illustrating an upper electrode according to one preferred embodiment of the present invention.

### DESCRIPTION OF THE PREFERRED EMBODIMENTS

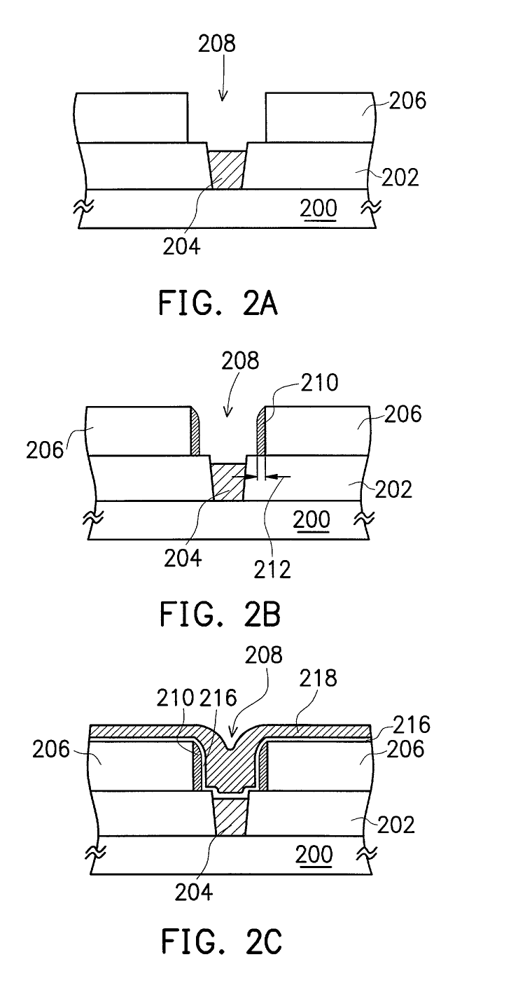

Referring to FIG. 2A, a dielectric layer 206 is formed on a semiconductor substrate 200 having a dielectric layer 202 thereon by, for example, chemical vapor deposition (CVD). A node contact window 204 is formed in the dielectric layer 206. The material of the dielectric layer 206 can be silicon oxide. A portion of the dielectric layer 206 is removed, thereby forming the opening 208, which exposes the node contact window 204. The formation process of the opening 208 uses lithographic technique and anisotropic etching.

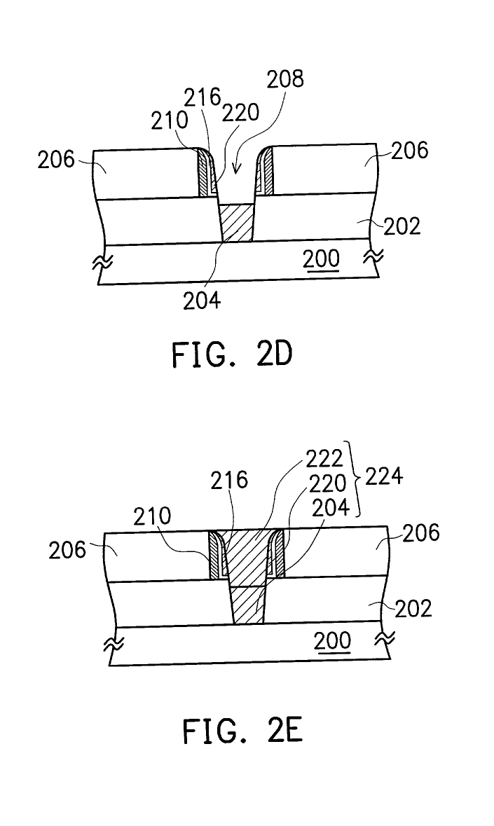

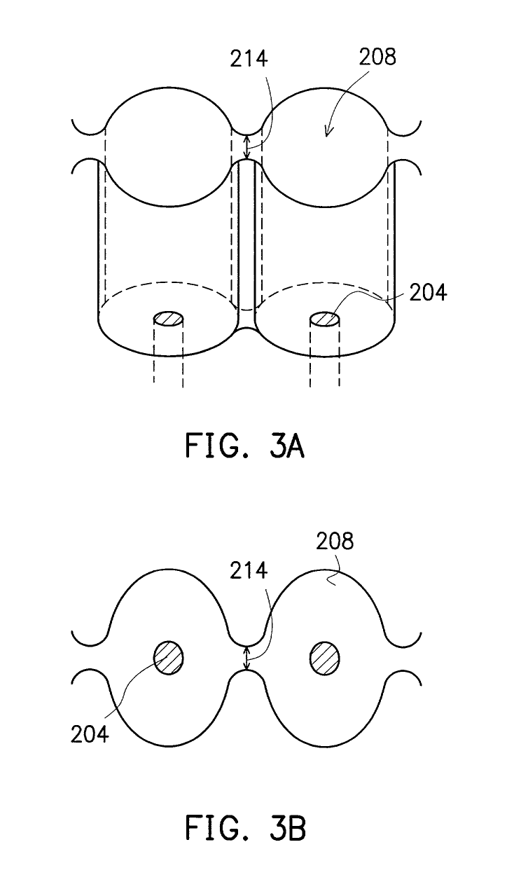

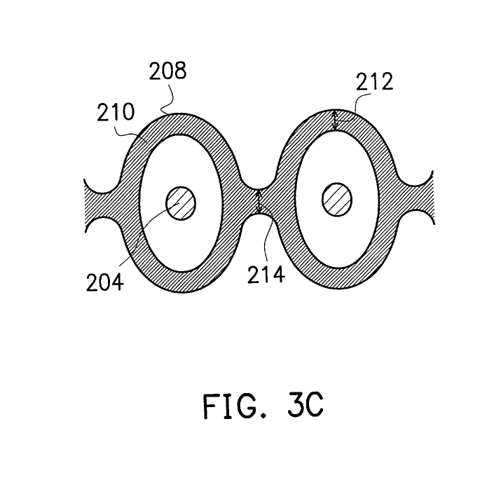

The side-view diagram of the opening 208 formed in the present invention is illustrated in FIG. 3A. The present invention uses lithographic etching to form a plurality of cylindrical openings 208 within the dielectric layer 206 (not illustrated) and each opening 208 exposes the node contact window 204. Since the special features of the present invention lies in the reverse electrode structure and because the upper electrodes of the capacitors must be electrically connected to each other, therefore, during formation of the plurality of openings 208, the adjacent openings 208 must be connected to each other. And a neck-shaped structure 214 is formed where the two adjacent openings 208 connect.

FIG. 3B is the top view of FIG. 3A. From FIG. 3B, it can be clearly seen that the openings 208 expose the node contact window 204 and the opening 208, while the adjacent openings 208 are connected to each other, forming a neck-shaped structure 214 where the two adjacent openings 208 connect.

Subsequently, referring to FIG. 2B, a conductive spacer 210 is formed on the sidewall of the opening 208. The formation process of the conductive spacer 210 includes forming a conductive layer on the surface of the above-described structure, using a process such as CVD, and the material used can be polysilicon or amorphous polysilicon. A portion of the conductive layer is removed, and the removal process uses anisotropic etching, for example, thereby forming a conductive spacer 210 on the inside wall of the opening 208. The thickness of the conductive layer is indicated in the diagram as 212.

FIG. 3C is the top view of FIG. 2B. The thickness 212 of the conductive spacer 210 formed within the opening 208 region is the same or greater than half of width of the neck-shaped structure 214, enabling the conductive spacer 210 on the neck-shaped structure 214 region to connect to each other and to be used as the upper electrode. The arrow line indicated by the lead line for the reference number 214 is the width of the neck shaped structure 214. The hemispherical grain layer or selected hemispherical grain layer is formed on top of the upper electrode, thereby increasing the surface area of the capacitor. The hemispherical grain layer or selected hemispherical grain layer is formed by a process such as CVD.

Subsequently, referring to FIG. 2C, a thin dielectric layer 216 is formed upon the semiconductor structure, covered the inside surface of the opening 208 and the surface of the dielectric layer 206. The formation process of the thin dielectric layer 216 can be CVD, and the material used to form the dielectric layer can be an ONO structure or tantalum oxide. A conductive layer 218 is formed above the dielectric layer 216 and the formation process can be CVD, and the material used is polysilicon, for example.

Referring to FIG. 2D, the dielectric 206 is used as the etching endpoint. The conductive layer 218 and the dielectric layer 216 on outside of the opening 208 are removed, exposing the surface of the node contact window 204 within the opening 208. Also, a portion of the dielectric layer 216 and a conductive spacer 220 are left on the conductive spacer 210 of the sidewall of the opening 208. The entire spacer structure is formed of the conductive spacer 210, the dielectric layer 216 and the conductive spacer 220. The removal process of the conductive layer 218 and the dielectric layer 216 is anisotropic etching, for example.

Referring to FIG. 2E, a conductive layer 222 is formed in the above-described structure, filling in the opening 208, so that the combination of the conductive layer 222 and the conductive spacer 220 and the node contact window 204 to form the lower electrode 224 of the capacitor, thereby completing the formation of the cylinder capacitor. The conductive layer 220 is made of a material such as polysilicon, and is formed by a process such as CVD. After a polysilicon layer is covered inside the opening 208 and upon the dielectric layer 206, an etchback process or CMP is used to remove the polysilicon layer covering the surface of the dielectric layer 206. Thus, the polysilicon layer inside the opening 208 remains and forms a portion of the lower electrode of the capacitor.

The cylinder capacitor formed in the present embodiment has a reverse electrode structure. The structure is ordered from the sidewall as upper electrode, dielectric layer and lower electrode. Furthermore, the lower electrode is located inside the opening 208 and is electrically connected to the conductive material inside the node contact window 204.

From the above-described invention, it can be seen that the important feature of the present invention is formation of a reverse electrode structure in cylinder capacitor. The formation process of the capacitor includes first forming the upper electrode, forming the dielectric layer thereon, and forming the lower electrode, and that it has a reverse electrode structure. The structure of the capacitor is different from the capacitor electrode structure in the related art.

Moreover, during the formation process of the capacitor, due to the changes in the capacitor electrode structure, the CMP slurry is prevented from entering into the cylinder structure and contaminating the lower electrode and the dielectric layer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing a cylinder capacitor having a reverse electrode, applicable to a substrate having a first dielectric layer and a node contact window are already formed thereon, comprising:
forming a second dielectric layer on the first dielectric layer and the node contact window;
removing a portion of the second dielectric layer for forming a plurality of openings, wherein the openings expose the node contact window, and each opening connects with an adjacent opening;
forming a first conductive spacer on sidewalls of the openings, thereby forming an upper electrode;
successively forming a third dielectric layer and a second conductive spacer on the first conductive spacer; and
forming a first conductive layer to fill the openings, wherein the first conductive layer and the second conductive spacer together form a lower electrode.

2. The method of manufacturing a reverse electrode cylinder capacitor structure as claimed in claim 1, wherein the step of forming the first conductive spacer comprises:
forming a second conductive layer within the openings and covering the second dielectric layer; and
performing etchback on the second conductive layer, thereby completing removal of the second conductive layer outside of the openings, and forming a first conductive spacer on the sidewalls of the openings.

3. The method of manufacturing a reverse electrode cylinder capacitor structure as claimed in claim 2, wherein a material of the first conductive spacer is polysilicon or amorphous silicon.

4. The method of manufacturing a reverse electrode cylinder capacitor structure as claimed in claim 2, wherein the etchback process of the second conductive layer includes anisotropic etching.

5. The method of manufacturing a reverse electrode cylinder capacitor structure as claimed in claim 2, wherein a neck-shaped structure is formed where each opening connects with an adjacent opening, and the first conductive spacer is connected to the neck-shaped structure.

6. The method of manufacturing a reverse electrode cylinder capacitor structure as claimed in claim 2, which further includes formation of a selective hemispherical grain layer or a hemispherical grain layer on the first conductive spacer.

7. The method of manufacturing a reverse electrode cylinder capacitor structure as claimed in claim 1, wherein the formation process of the third dielectric layer and the second conductive spacer comprises:
successively forming a fourth dielectric layer and a third conductive layer within the openings and covers the first conductive spacer and the second dielectric layer; and
performing etchback on the third conductive layer and the fourth dielectric layer, thereby completing a removal of the third conductive layer and the fourth dielectric layer outside the openings and the node contact window; and forming the third conductive layer and the second conductive spacer on the first conductive spacer.

8. The method of manufacturing a reverse electrode cylinder capacitor structure as claimed in claim 7, wherein the etchback process of the third conductive layer and the fourth dielectric layer includes anisotropic etching.

9. The method of manufacturing a reverse electrode cylinder capacitor structure as claimed in claim 7, wherein a material of the second conductive spacer includes polysilicon deposited by chemical vapor deposition.

10. A method of manufacturing a reverse electrode cylinder capacitor structure, suitable for use on a substrate, having a first dielectric layer and a node contact window already formed thereon, comprising:
forming a second dielectric layer on the first dielectric layer and the node contact window;
removing a portion of the second dielectric layer, thereby forming a plurality of openings, wherein the openings expose the node contact window, and each opening connects with an adjacent opening, while a neck-shaped structure is formed where each opening connects with an adjacent opening;
forming a first conductive layer within the openings and on the second dielectric layer;
using anisotropic etching to etchback the first conductive layer, thereby completing a removal of the first conductive layer outside of the opening; forming a first conductive spacer on the side wall of the openings, thereby forming an upper electrode, wherein the first conductive spacer is connected to the neck-shaped structure;
successively forming a third dielectric layer and a second conductive layer within the openings and covering the first conductive spacer and the second dielectric layer;
using anisotropic etching to etchback the second conductive layer and the third dielectric layer, thereby completing a removal of the second conductive layer and the third dielectric layer covering outside the openings and the node contact window;
forming a fourth dielectric layer and a second conductive spacer on the first conductive spacer; and
forming a third conductive layer to fill the opening, wherein the third conductive layer and the second conductive layer form a lower electrode.

11. The method of manufacturing a reverse electrode cylinder capacitor structure as claimed in claim 10, wherein a material of the first conductive spacer includes either polysilicon or amorphous silicon.

12. The method of manufacturing a reverse electrode cylinder capacitor structure as claimed in claim 10, wherein the first conductive spacer further includes forming either a selective hemispherical grain layer or a hemispherical grain layer.

13. The method of manufacturing a reverse electrode cylinder capacitor structure as claimed in claim 10, wherein a material of the second conductive spacer includes polysilicon deposited by chemical vapor deposition.

14. A method of manufacturing a reverse electrode cylinder capacitor structure, suitable for use on a substrate, having a first dielectric layer and a node contact window formed thereon, comprising:
forming a second dielectric layer on the first dielectric layer and node contact window;
removing a portion of the second dielectric layer, thereby forming a plurality of windows, and the bottom of the openings expose the node contact window; any one of the openings is connected to any one of the adjacent openings, wherein a neck-shaped structure is formed in the connecting region;
forming an upper electrode inside the openings; and
successively forming a third dielectric layer and a lower electrode above the upper electrode.

15. The method of manufacturing a reverse electrode cylinder capacitor structure as claimed in claim 14, wherein forming the upper electrode comprises:
forming a first conductive layer within the openings and covering the second dielectric layer; and
performing etchback on a conductive layer, thereby completing the removal of the first conductive layer outside of the openings and forming the upper electrode on the sidewall of the openings.

16. The method of manufacturing a reverse electrode cylinder capacitor structure as claimed in claim 15, wherein the etchback process of the first conductive layer includes anisotropic etching.

17. The method of manufacturing a reverse electrode cylinder capacitor structure as claimed in claim 14, wherein the upper electrodeconnects with the neck-like structure.

18. The method of manufacturing a reverse electrode cylinder capacitor structure as claimed in claim 14, further including forming either a selective hemispherical grain layer or a hemispherical grain layer.

19. The method of manufacturing a reverse electrode cylinder capacitor structure as claimed in claim 14, wherein the formation of the third dielectric layer and the lower electrode comprise:
successively forming a third dielectric layer and a second conductive layer within the openings and covering the first conductive spacer and the second dielectric layer;
performing etchback on the second conductive layer and the third dielectric layer, thereby completing the removal of the second conductive layer and the third dielectric layer covering the outside of the openings and the node contact window; forming a fourth dielectric layer and a second conductive spacer on the first conductive spacer; and
forming a third conductive layer to fill the opening, wherein the third conductive layer and the second conductive spacer form a lower electrode.

20. The method of manufacturing a reverse electrode cylinder capacitor structure as defined in claim 19, wherein the etchback process of the second conductive layer and the third conductive layer includes anisotropic etching.
